(19) United States
(12) Patent Application Publication
(10) Pub. No.: US 2026/0082517 A1
(43) Pub. Date: Mar. 19, 2026

(54) SERVER

(71) Applicants: SQ TECHNOLOGY (SHANGHAI) CORPORATION, Shanghai (CN); INVENTEC CORPORATION, Taipei (TW)

(72) Inventors: Shuai Zhang, Shanghai (CN); Fanpu He, Shanghai (CN); Xiaoshuang Li, Shanghai (CN); Guangzhao Tian, Shanghai (CN); Hong-Chou Lin, Taipei (TW); Yu-Fan Chen, Taipei (TW)

(21) Appl. No.: 18/991,395

(22) Filed: Dec. 21, 2024

(30) Foreign Application Priority Data
Sep. 13, 2024 (CN) 202411289894.0

(51) Int. Cl. H05K 7/20; H05K 7/10; H05K 7/14

(52) U.S. Cl. CPC H05K 7/20727; H05K 7/10; H05K 7/1457; H05K 7/1489; H05K 7/20145; H05K 7/20154; H05K 7/20172

(57) ABSTRACT

A server includes a housing provided with an accommodating cavity; a main processor assembly, a graphics processing card assembly, and a graphics processing card backplane that are accommodated in the accommodating cavity, wherein a gap is formed between the graphics processing card backplane and a bottom portion of the housing, a first side of the graphics processing card backplane is provided with a plurality of connecting interfaces, the graphics processing card assembly is connected to the plurality of connecting interfaces, a second side of the graphics processing card backplane is provided with a plurality of data transmission chips, and the plurality of data transmission chips are electrically connected to the plurality of connecting interfaces, respectively; and a heat dissipation assembly provided adjacent to the graphics processing card assembly, the heat dissipation assembly being configured to dissipate heat from the graphics processing card assembly and the plurality of data transmission chips.

### CROSS-REFERENCE TO RELATED APPLICATIONS

This application claims priority of Chinese Patent Application No. 202411289894.0, filed on Sep. 13, 2024, entitled “SERVER”, the entire content of which is incorporated herein by reference in its entirety.

### TECHNICAL FIELD

The present disclosure relates to the technical field of servers, in particular to a server.

### BACKGROUND

With the rise of internet short video platform and the rapid development of its business model, servers that can process videos and games need to satisfy higher requirements. The servers should not only be able to efficiently handle large-scale video transcoding tasks to satisfy the rapid distribution needs of high-quality audio and video content, but also provide a smooth online gaming experience to ensure that players can enjoy high-quality gaming services. Therefore, the design of the server should not only consider the computing performance, but also focus on solving the heat dissipation problem to ensure the stable operation of the system and prolong the service life of the hardware.

The server generally employs an intensive computing architectures that includes a large number of processors to speed up data processing. However, since the processors generate a lot of heat when running, if effective heat dissipation measures are not taken, the server will be overheated, which will affect system stability and may shorten the service life of the hardware.

Therefore, how to improve the heat dissipation efficiency of the server has become an urgent problem to be solved.

### SUMMARY

Accordingly, it is necessary to provide a server that improves the heat dissipation efficiency of the server.

A server is provided includes:
a housing provided with an accommodating cavity;
a main processor assembly accommodated in the accommodating cavity;
a graphics processing card assembly accommodated in the accommodating cavity;
a graphics processing card backplane accommodated in the accommodating cavity, wherein a gap is formed between the graphics processing card backplane and a bottom portion of the housing, a first side of the graphics processing card backplane is provided with a plurality of connecting interfaces, the graphics processing card assembly is connected to the plurality of connecting interfaces, a second side of the graphics processing card backplane is provided with a plurality of data transmission chips, and the plurality of data transmission chips are electrically connected to the plurality of connecting interfaces, respectively; and
a heat dissipation assembly provided adjacent to the graphics processing card assembly and in communication with external air, wherein the heat dissipation assembly is configured to dissipate heat from the graphics processing card assembly and the plurality of data transmission chips.

In one of the embodiments, the server further includes a supporting member, two ends of the supporting member are in contact with the second side of the graphics processing card backplane and the bottom portion of the housing, respectively, as to form the gap between the graphics processing card backplane and the bottom portion of the housing.

In one of the embodiments, the graphics processing card assembly includes:
a limiting member provided with a plurality of limiting grooves; and
a plurality of graphics processing cards respectively accommodated in the plurality of limiting grooves and respectively electrically connected to the plurality of connecting interfaces.

In one of the embodiments, the housing includes an upper cover, a bottom plate, and two side plates, the two side plates are provided on two opposite sides of the bottom plate, respectively, the upper cover, the bottom plate, and the side plates cooperatively enclose the accommodating cavity, the housing further includes two sliding rails symmetrically provided on the two side plates, and the graphics processing card assembly is slidably connected to the two side plates through the two sliding rails.

In one of the embodiments, the housing further includes a mounting structure fixedly connected to the bottom plate and the two side plates, and the mounting structure is detachably connected to the upper cover.

In one of the embodiments, the heat dissipation assembly includes a fan backplane and a plurality of heat dissipation fans connected to the fan backplane, the mounting structure includes a plurality of fan limiting channels, and the plurality of heat dissipation fans are detachably mounted in plurality of fan limiting channels, respectively.

In one of the embodiments, the server further includes a power supply assembly including a power supply backplane and a plurality of power supplies connected to the power supply backplane, the mounting structure includes a plurality of power supply limiting channels, and the plurality of power supplies are detachably mounted in the plurality of power supply limiting channels, respectively.

In one of the embodiments, the server further includes a plurality of data transmission interfaces provided on an outer side wall of the side plate.

In one of the embodiments, the main processor assembly is detachably connected to the bottom plate.

In one of the embodiments, the server further includes a pluggable optical assembly board provided on the second side of the graphics processing card backplane and connected to the graphics processing card backplane.

According to the server, the plurality of connecting interfaces configured to connected to the graphics processing card assembly are provided on the first side of the graphics processing card backplane, and the plurality of data transmission chips are provided on the second side of the graphics processing card backplane, a heat dissipation air channel of the graphics processing card assembly and a heat dissipation air channel of the data transmission chips are separated. The heat dissipation assembly is adjacent to the graphics processing card assembly and is in communication with the external, so that the heat generated by the graphics processing card assembly and the data transmission chips can be effectively and rapidly transmitted to the external air through the corresponding heat dissipation air channel, thereby significantly improving the heat dissipation efficiency of the server and ensuring the stable operation of the system, avoiding the hardware damage caused by overheating, and prolonging the service life of the server and improving the service quality of the server.

The details of one or more embodiments of the application are set forth in the accompanying drawings and the description below. Other features, objects, and advantages of the application will be apparent from the description and drawings, and from the claims.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 is an exploded view of a server according to an embodiment.

FIG. 2 is a perspective view of the server of FIG. 1 after removing an upper cover.

FIG. 3 illustrates a first side of a graphics processing card backplane according to an embodiment.

FIG. 4 illustrates a second side of the graphics processing card backplane according to an embodiment.

FIG. 5 is a cross-sectional view of FIG. 2.

FIG. 6 is an exploded view of a graphics processing card assembly according to an embodiment.

FIG. 7 is a perspective view of a graphics processing card according to an embodiment.

FIG. 8 is a first perspective view of a server according to an embodiment.

FIG. 9 is a second perspective view of the server according to an embodiment.

FIG. 10 is a third perspective view of the server according to an embodiment.

FIG. 11 is a fourth perspective view of the server according to an embodiment.

FIG. 12 is a front view of the server according to an embodiment.

FIG. 13 is a perspective view of a housing and a main processor assembly according to an embodiment.

### DETAILED DESCRIPTION OF THE EMBODIMENTS

In order to make the above objectives, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuths or position relationships shown in the attached drawings. These terms are only for the convenience of describing the present disclosure and simplifying the description, rather than indicating or implying that the indicated devices or elements must have the specific azimuths, or be constructed or operated in the specific azimuths, and therefore such terms cannot be understood as limitations of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “couple”, “fix” and the like should be interpreted broadly. For example, the terms can mean fixed connection, detachable connection, or being integrated. The terms can mean mechanical connection or electrical connection. The terms can mean directly connection or indirectly connection through an intermediate medium. The terms can mean connection within two elements or interaction relationship between two elements, unless otherwise expressly limited. For those skilled in the art, the specific meaning of the above terms in the present disclosure should be understood according to the specific situation.

In the present disclosure, unless otherwise expressly specified and limited, a first feature “above” or “below” a second feature may be in direct contact with the second feature, or the first and second features may be in indirect contact through an intermediate medium. Moreover, the first feature “above” the second feature may be right above or obliquely above the second feature, or the first feature may be merely located at a height higher than the second feature. The first feature “below” the second feature may be right below or obliquely below the second feature, or the first feature may be merely located at a height lower than that of the second feature.

It should be noted that when an element is called “fixed to” or “mounted on” another element, it can be directly on another element or there can be an intermediate element. When an element is considered to be “connected” to another element, it can be directly connected to another element or there can be an intermediate element. The terms “vertical”, “horizontal”, “up”, “down”, “left”, “right” and similar expressions used herein are for the purpose of illustration only and do not represent the only ways for implementation.

In the description of this specification, the description with reference to the terms “some embodiments”, “other embodiments”, etc. means that the specific features, structures, materials or characteristics described in conjunction with the embodiment or example are included in at least one embodiment or example of the present disclosure. In this specification, the illustrative descriptions of the above terms do not necessarily refer to the same embodiment or example.

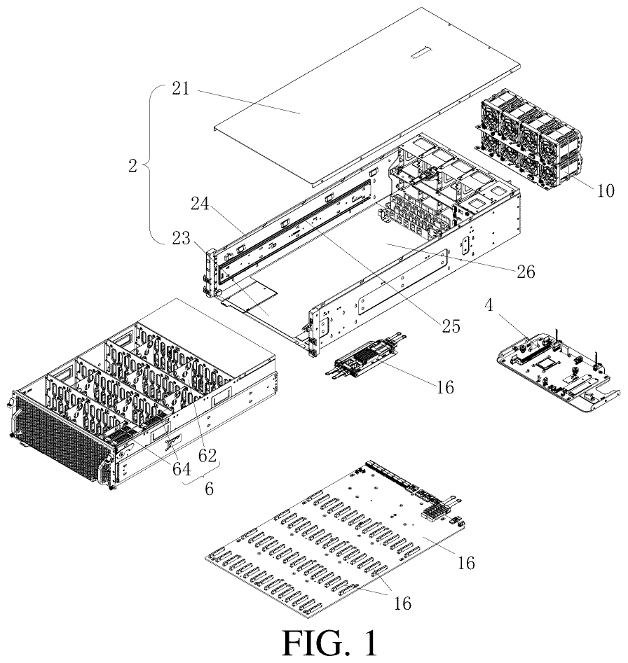

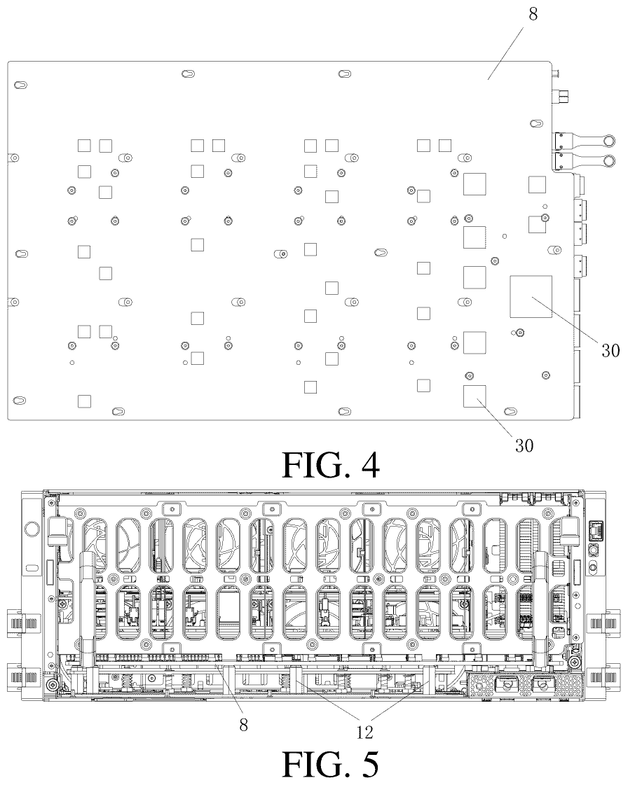

In an embodiment, as shown in FIG. 1, a server is provided, including a housing 2, a main processor assembly 4, a graphics processing card assembly 6, a graphics processing card backplane 8, and a heat dissipation assembly 10. The housing 2 is provided with an accommodating cavity 26. The main processor assembly 4, the graphics processing card assembly 6, and the graphics processing card backplane 8 are accommodated in the accommodating cavity 26. A gap is formed between the graphics processing card backplane 8 and a bottom portion of the housing 2. A first side of the graphics processing card backplane 8 is provided with a plurality of connecting interfaces 82, and the graphics processing card assembly 6 is connected to the plurality of connecting interfaces 82. Referring to FIG. 4, a second side of the graphics processing card backplane 8 is provided with a plurality of data transmission chips 30. The plurality of data transmission chips 30 are electrically connected to the plurality of connecting interfaces 82, respectively. The heat dissipation assembly 10 is provided adjacent to the graphics processing card assembly 6 and is in communication with external air. The heat dissipation assembly 10 is configured to dissipate heat from the graphics processing card assembly 6 and the plurality of data transmission chips 30.

The housing 2 is an external frame or a computing case of the server, which has the accommodating cavity 26 configured to provide physical protection and support for electronic components in the accommodating cavity 26. The main processor assembly 4 refers to a central processing unit (CPU) in the server, including at least a server CPU and a CPU motherboard, which are configured to perform most computing tasks and control operations of the server. The graphics processing card assembly 6 refers to a specific hardware configured to perform graphics processing in the server, and may be in the form of a GPU (graphics processing unit) card. In the server, the graphics processing card assembly 6 can significantly accelerate video transcoding and rendering tasks. In an embodiment, the graphics processing card assembly 6 may be composed of a plurality of independent GPU cards. For example, as shown in FIG. 1, the graphics processing card assembly 6 may be composed of a limiting member 62 and a plurality of graphics processing cards 64. The limiting member 62 may include an outer wall and an inner frame structure that are integrally formed. The graphics processing card backplane 8 refers to a circuit board. The plurality of connecting interfaces 82 are provided on a top surface of the graphics processing card backplane 8 and are configured to mount with the GPU cards in the graphics processing card assembly 6. The data transmission chips 30 are provided on a bottom surface of the graphics processing card backplane 8 and are configured to process communication and data exchange between the GPU cards. The heat dissipation assembly 10 is configured to adjust a temperature inside the server, and is mainly configured to dissipate heat generated by the graphics processing card assembly 6 and the data transmission chips 30. The heat dissipation assembly 10 may include a heat dissipation device such as a fan, a heat sink, a liquid cooling system, etc., to transfer heat from an interior of the server to the external air, thereby keeping the temperature inside the server within a safe range.

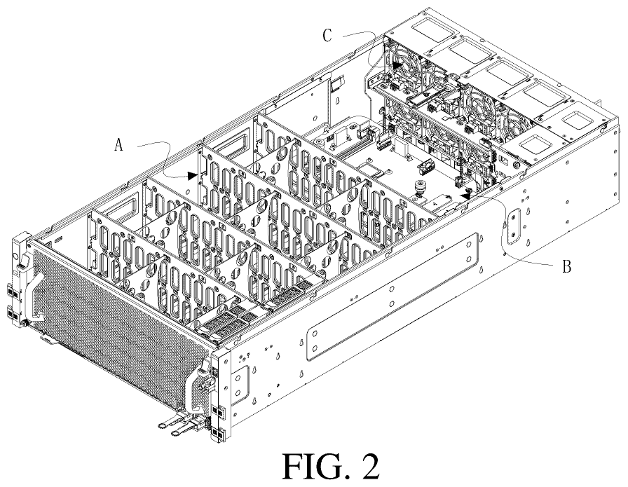

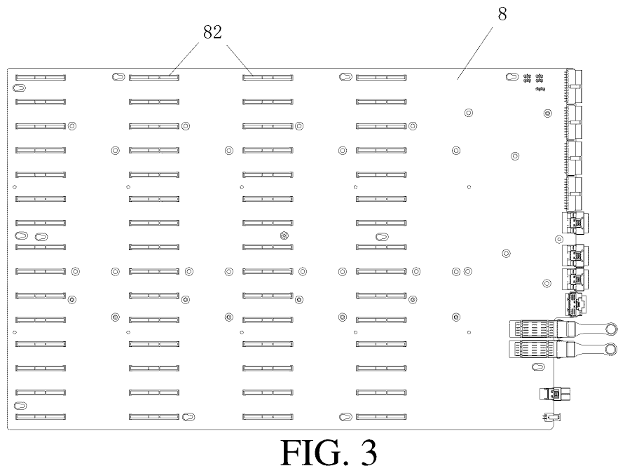

For example, as shown in FIG. 1 and FIG. 2, the accommodating cavity 26 of the housing 2 is mainly divided into three different areas. A first accommodating area A is configured to accommodate the graphics processing card assembly 6 and the graphics processing card backplane 8. A second accommodating area B is configured to accommodate the main processor assembly 4. A third accommodating area C is configured to accommodate the heat dissipation assembly 10. The main processor assembly 4 is electrically connected to the graphics processing card assembly 6 through the graphics processing card backplane 8, and the main processor assembly 4 is further electrically connected to the heat dissipation assembly 10. Based on the above connections, tasks such as video transcoding and rendering when the server processes the video and game can be completed under the cooperation of the main processor assembly 4, the graphics processing card assembly 6, and the graphics processing card backplane 8. During the process of video transcoding and rendering, the graphics processing card assembly 6 and the plurality of data transmission chips 30 on the graphics processing card backplane 8 may generate a large amount of heat. If the heat cannot be transmitted to the external air in time, the graphics processing card assembly 6 and the data transmission chips 30 may be overheated and damaged. For the above reasons, the plurality of connecting interfaces 82 connected to the graphics processing card assembly 6 are provided on the first side of the graphics processing card backplane 8, so that the graphics processing card assembly 6 is connected to the first side of the graphics processing card backplane 8 through the connecting interfaces 82, as shown in FIG. 3. The plurality of data transmission chips 30 are provided on the second side of the graphics processing card backplane 8, as shown in FIG. 4. Through the above arrangement, a heat dissipation air channel of the graphics processing card assembly 6 and a heat dissipation air channel of the data transmission chip 30 are separated through the graphics processing card backplane 8, so that the heat generated by the graphics processing card assembly 6 and the data transmission chip 30 can be transmitted to the external air through the corresponding heat dissipation air channel as much as possible under the heat dissipation effect of the heat dissipation assembly 10, thereby achieving efficient heat dissipation.

According to the server, the accommodating cavity 26 in the housing 2 is divided into three different areas, which respectively provide specific space for the graphics processing card assembly 6 and the graphics processing card backplane 8, the main processor assembly 4, and the heat dissipation assembly 10, so that the main processor assembly 4 can realize efficient data interaction with the graphics processing card assembly 6 through the graphics processing card backplane 8 and completes the tasks such as video transcoding and rendering. Meanwhile, the plurality of connecting interfaces 82 configured to be connected to the graphics processing card assembly 6 are provided on the first side of the graphics processing card backplane 8, and the plurality of data transmission chips 30 are provided on the second side of the graphics processing card backplane 8, a heat dissipation air channel of the graphics processing card assembly 6 and a heat dissipation air channel of the data transmission chips 30 are separated. The heat dissipation assembly 10 is adjacent to the graphics processing card assembly 6 and is in communication with the external, so that the heat generated by the graphics processing card assembly 6 and the data transmission chips 30 can be effectively and rapidly transmitted to the external air through the corresponding heat dissipation air channel, thereby significantly improving the heat dissipation efficiency of the server and ensuring the stable operation of the system, avoiding the hardware damage caused by overheating, and prolonging the service life of the server and improving the service quality of the server.

In an exemplary embodiment, as shown in FIG. 5, the server further includes a supporting member 12. Two ends of the supporting member 12 are in contact with the second side of the graphics processing card backplane 8 and the bottom portion of the housing 2, respectively, so that the gap is formed between the graphics processing card backplane 8 and the bottom portion of the housing 2.

The supporting member 12 may be a screw fixing the graphics processing card backplane 8. The supporting member 12 is configured to ensure a sufficient space between the backplane 8 of the graphics processing card and the bottom of the housing 2, so as to form the gap that is conducive to air circulation, thereby improving the heat dissipation effect.

For example, as shown in FIG. 5, since the two ends of the supporting member 12 are respectively in contact with the second side of the graphics processing card backplane 8 and the bottom portion of the housing 2, the gap is formed between the graphics processing card backplane 8 and the bottom portion of the housing 2. It should be noted that a height of the gap is determined by a height of the supporting member 12. In order to satisfy different heat dissipation requirements, the supporting member 12 with different heights may be selected according to actual requirements, so as to adjust a height of the heat dissipation air channel of the graphics processing card assembly 6 and a height of the heat dissipation air channel of the data transmission chips 30, thereby ensuring that the heat dissipation efficiency satisfies the heat dissipation requirements.

In the embodiment, by providing the support 12, the server can more effectively control the internal heat distribution, especially control the heat generated by the graphics processing card assembly 6 and the data transmission chip 30. When the server performs high-load tasks such as video transcoding and rendering, the graphics processing card assembly 6 and the data transmission chip 30 can generate great amount of heat. At this time, the heat generated by the data transmission chip 30 can be better guided to the external air through the gap between the graphics processing card backplane 8 and the bottom portion of the housing 2 by the heat dissipation mechanism of the heat dissipation assembly 10 in communication with the external air, which effectively prevents the overheating phenomenon, and ensures the stable operation of the server and prolongs the service life of the hardware.

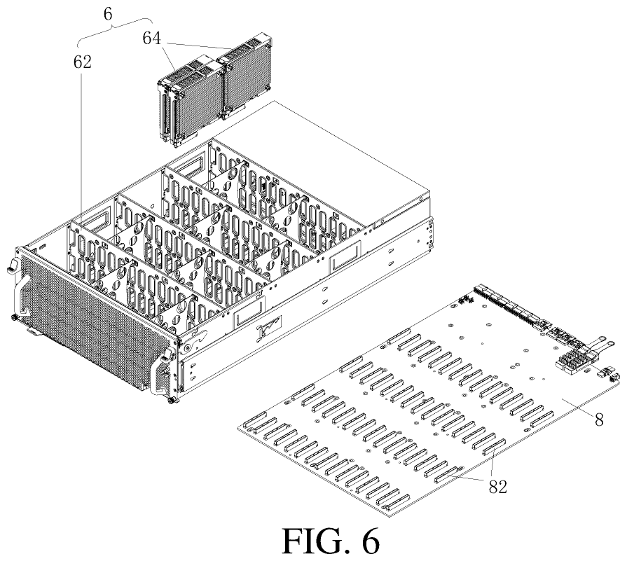

In an exemplary embodiment, as shown in FIG. 6, the graphics processing card assembly 6 includes a limiting member 62 and a plurality of graphics processing cards 64. The limiting member 62 is provided with a plurality of limiting grooves. The plurality of graphics processing cards 64 are respectively accommodated in the plurality of limiting grooves and respectively electrically connected into the plurality of connecting interfaces 82.

The limiting member 62 may include an outer wall and an inner frame structure that are integrally formed. The limiting member 62 is configured to fix the graphics processing card 64 in the accommodating cavity 26, so as to prevent the graphics processing card 64 from moving during the operation of the server, especially when the server is subjected to slight vibration or impact. The limiting member 62 may be made of metal or high-strength plastic to ensure sufficient robustness and durability. The limiting grooves may be recesses or openings formed on the inner frame structure of the limiting member 62. The number of the limiting grooves is the same as the number of the graphics processing cards 64. The shape and size of each of the limiting grooves are adapted to the shape and size graphics processing card 64, so that the graphics processing cards 64 can be accurately inserted into the corresponding limiting grooves and thus be firmly fixed in the correct position.

For example, by inserting the graphics processing cards 64 into the limiting grooves on the limiting member 62 and electrically connecting the graphics processing cards 64 into the plurality of connecting interfaces 82 on the first side of the graphics processing card backplane 8, the reliable fixing and the good electrical connection of the graphics processing card assembly 6 inside the server can be ensured.

In the embodiment, the plurality of graphics processing cards 64 in the graphics processing card assembly 6 are fixed through the limiting members 62 and the limiting grooves, so that the reliable fixation and the good electrical connection of the graphics processing cards 64 in the server are ensured, which not only improves the stability and the reliability of the system and simplifies the assembly and disassembly processes of the graphics processing cards 64, but also ensures the stable position of the graphics processing card assembly 6, further enhances the working efficiency of the heat dissipation assembly 10, ensures that the internal temperature of the server can be effectively controlled when the server performs the high-load task, avoids the occurrence of the overheating phenomenon, thereby ensuring the stable operation of the server and prolonging the service life of the hardware.

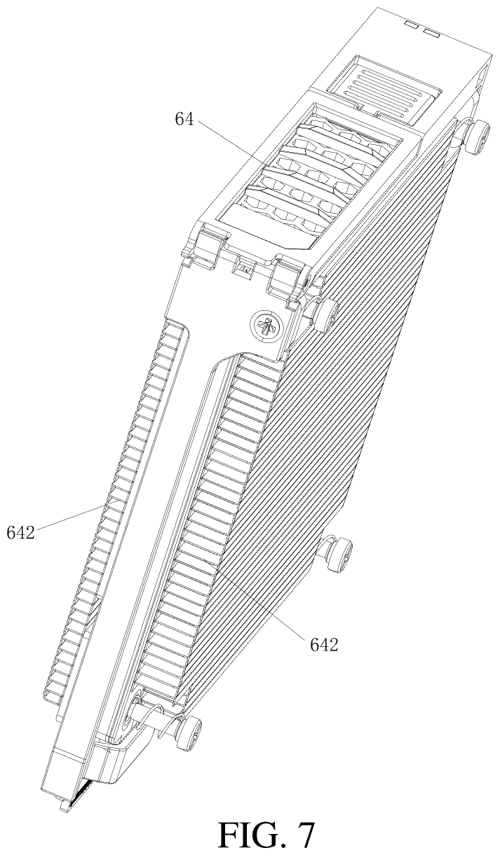

In an exemplary embodiment, as shown in FIG. 7, two sides of each graphics processing card 64 are each provided with a heat dissipation member 642. Each heat dissipation member 642 has a first side in contact with the graphics processing card 64 and a second side away from the graphics processing card 64. A plurality of heat dissipation air channels are formed between the first side of the heat dissipation member 642 and the second side of the heat dissipation member 642, so as to dissipate heat from the graphics processing card 64 when the heat dissipation assembly operates. The first side of the heat dissipation member 642 is made of a thermally conductive material, and the second side of the heat dissipation member 642 is made of a thermally insulating material.

As shown in FIG. 7, two sides of each graphics processing card 64 are each provided with the heat dissipation member 642. The heat dissipation member 642 is of a grid structure. The first side of the heat dissipation member 642 can be directly in contact with a surface of the graphics processing card 64, so as to absorb and dissipate heat. The heat dissipation air channels refer to channels provided in or around the heat dissipation member 642 to guide air flow. The heat dissipation air channels help to improve the speed of the air flow, thereby better transferring heat from the graphics processing card 64 to the heat dissipation assembly 10 to discharge the heat out of the server. The second side of the heat dissipation member 642 is made of a thermally insulating material, which can reduce the conduction of heat to other components (e.g., other graphics processing cards 64) and ensure that the heat can be effectively conducted to the heat dissipation assembly 10, thereby improving the heat dissipation efficiency and protecting other sensitive electronic components from being affected by high temperature.

When the heat dissipation assembly 10 is operated, the heat dissipation member 642 can effectively absorb the heat from the graphics processing card 64 and guide the heat to the heat dissipation assembly 10 through the plurality of heat dissipation air channels formed in the heat dissipation member 642. Since the first side of the heat dissipation member 642 is made of a thermally conductive material and the second side of the heat dissipation member 642 is made of a thermally insulating material, the heat dissipation member 642 can not only ensure effective transfer of heat, but also reduce conduction of heat to other components, thereby ensuring that the temperature in the server is effectively controlled.

In the embodiment, the heat dissipation members 642 are provided on both sides of each graphics processing card 64, and the heat dissipation member 642 is formed the plurality of heat dissipation air channels and is made of a thermally insulating material, so that the heat dissipation efficiency of the graphics processing card 64 can be effectively improved when the heat dissipation assembly 10 is operated and the internal temperature of the server can be ensured to be controlled when the server performs a high-load task. Overheating is avoided, thereby ensuring the stable operation of the server, prolonging the service life of the hardware, and improving the overall reliability and service quality of the server.

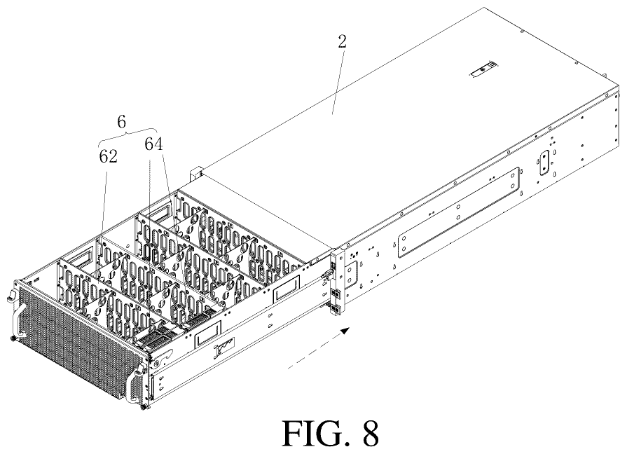

In an exemplary embodiment, as shown in FIG. 8, the housing 2 includes an upper cover 21, a bottom plate 23, and two side plates 24. The two side plates 24 are provided on two opposite sides of the bottom plate 23, respectively. The upper cover 21, the bottom plate 23, and the side plates 24 cooperatively enclose the accommodating cavity 26. The housing 2 further includes two sliding rails 25 symmetrically provided on the two side plates 24. The graphics processing card assembly 6 is slidably connected to the two side plates 24 through the two sliding rails 25.

In the embodiment, the sliding rails 25 are symmetrically provided on the two side plates 24 of the housing 2, so that the entire graphics processing card assembly 6 is slidably connected to the two side plates 24 through the sliding rails 25. The graphics processing card assembly 6 can be mounted and dismounted conveniently, the maintenance process is simplified, the maintainability and expandability of the server are improved, and the stable fixation of the graphics processing card assembly 6 in the server is ensured. The potential risk of the graphics processing card assembly 6 caused by vibration is reduced, thereby ensuring the stable operation of the server and prolonging the service life of the hardware.

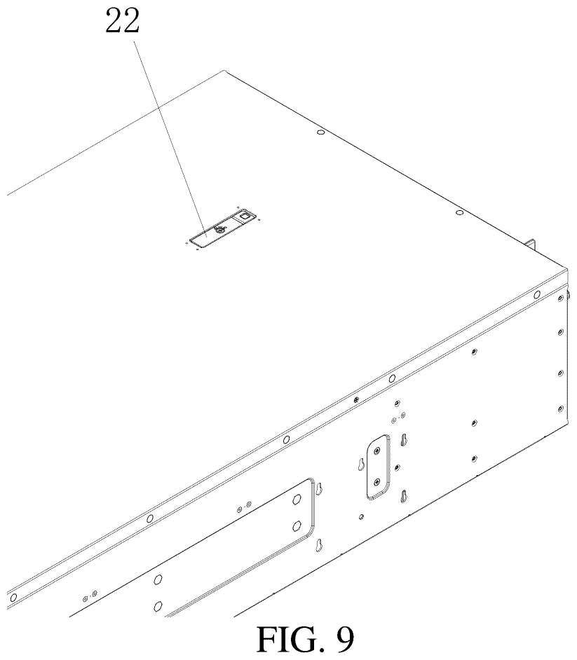

In an exemplary embodiment, as shown in FIG. 9, the housing 2 further includes a mounting structure 22 fixedly connected to the bottom plate 23 and the two side plates 24, and the mounting structure 22 is detachably connected to the upper cover 21.

For example, as shown in FIG. 9, the mounting structure 22 may be detachably connected to the upper cover 21 by a push-type buckle. When the upper cover 21 needs to be removed, the upper cover 21 can be removed by pressing the push-type buckle, so as to replace components in the accommodating cavity 26.

In the embodiment, the mounting structure 22 is provided in the housing 2, and the push-type buckle is detachably connected to the upper cover 21, so that the upper cover 21 can be easily mounted and dismounted, the replacement and maintenance processes of the components in the server are greatly simplified, the maintainability and expandability of the server are improved, and the components in the accommodating cavity 26 can be conveniently replaced, thereby improving the operation and maintenance efficiency of the server and reducing the maintenance cost.

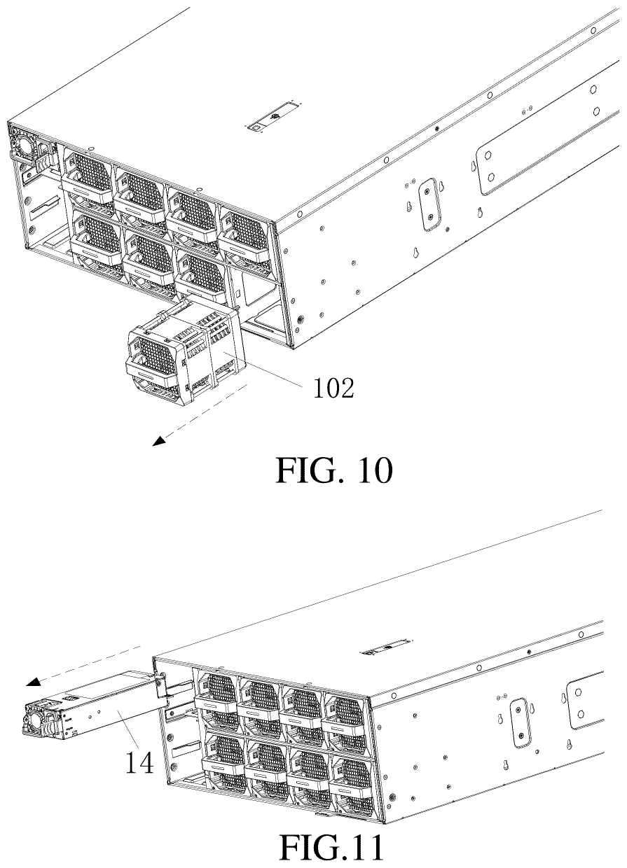

In an exemplary embodiment, as shown in FIG. 10, the heat dissipation assembly 10 includes a fan backplane (not shown) and a plurality of heat dissipation fans 102 connected to the fan backplane. The mounting structure 22 includes a plurality of fan limiting channels, and the plurality of heat dissipation fans 102 are detachably mounted in the plurality of fan limiting channels, respectively.

A type of the heat dissipation fan 102 can be selected according to the structure of the server, the heat dissipation requirement, in combination with the graph of the rotational speed and heat dissipation efficiency of the heat dissipation fan 102, the size of the heat dissipation fan 102, etc., which is not limited herein.

For example, when a certain heat dissipation fan 102 fails, it is only necessary to remove the failed heat dissipation fan 102 from the corresponding fan limiting channel without replacing the entire heat dissipation assembly 10.

In the embodiment, the heat dissipation assembly 10 includes the plurality of heat dissipation fans 102 that can be separately connected to the fan backplane, and the heat dissipation fans 102 are detachably mounted in the plurality of fan limiting channels of the mounting structure 22, so that when a certain heat dissipation fan 102 fails, only the failed heat dissipation fan 102 needs to be removed from the corresponding fan limiting channel for replacement. The entire heat dissipation assembly 10 does not need to be replaced, which greatly simplifies the maintenance process, reduces the maintenance cost, improves the maintainability and availability of the server, and ensures the stable operation and efficient heat dissipation of the server.

In an exemplary embodiment, as shown in FIG. 11, the server further includes a power supply assembly. The power supply assembly includes a plurality of power supplies 14 and a power supply backplane (not shown). The mounting structure 22 further includes a plurality of power supply limiting channels. The plurality of power supplies 14 are connected to the power supply backplane and detachably mounted in the plurality of power supply limiting channels, respectively.

A type of the power supply 14 can be selected according to the structure of the server and power supply requirements, in combination with the rated power of the power supply 14, the size of the power supply 14, etc., which is not limited herein.

For example, when a certain power supply 14 fails, it is only necessary to remove the failed power supply 14 from the corresponding power supply limiting channel without replacing the entire power supply assembly.

In the embodiment, the power supply assembly includes the plurality of power supplies 14 that can be separately connected to the power supply backplane, and the power supplies 14 are detachably mounted in the plurality of power supply limiting channels of the mounting structure 22, so that when a certain power supply 14 fails, only the failed power supply 14 needs to be removed from the corresponding power supply limiting channel for replacement. The entire power supply assembly does not need to be replaced, which greatly simplifies the maintenance process, reduces the maintenance cost, improves the maintainability and availability of the server, and ensures the stable operation and efficient power supply of the server.

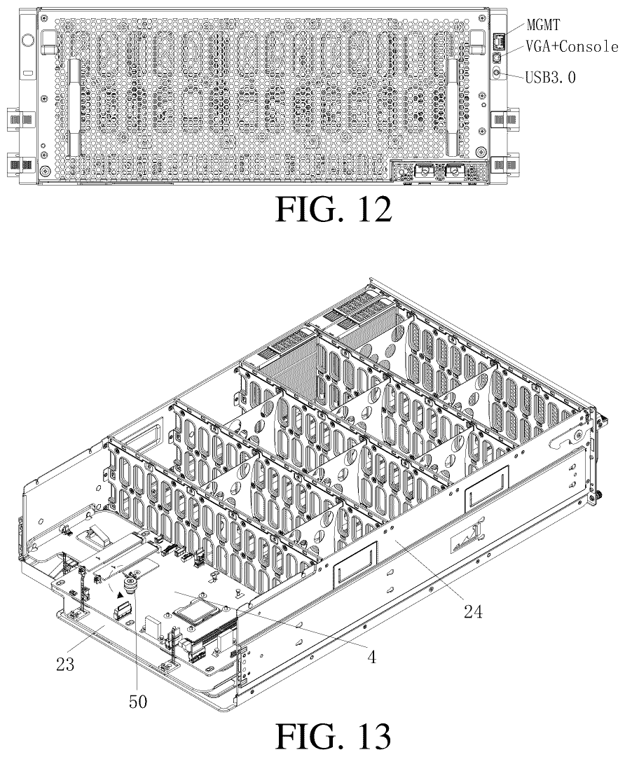

In an exemplary embodiment, as shown in FIG. 12, the server further includes a plurality of data transmission interfaces provided on an outer side wall of the side plate.

The plurality of data transmission interfaces include an MGMT port, a USB3.0 port, a VGA+Console port, etc.

In the embodiment, the plurality of data transmission interfaces, such as an MGMT port, a USB3.0 port, a VGA+Console port, an SYS-LED port, etc., are provided on the outer side wall of the side plate. Even if the data transmission interfaces are located in the housing 2, the interfaces can be easily accessed and conveniently connected to cables, thereby simplifying the cabling process of the server, improving maintainability and management convenience of the server, reducing cable confusion, and improving the cleanliness and management efficiency of the server.

In an exemplary embodiment, as shown in FIG. 13, the main processor assembly 4 is detachably connected to the bottom plate 23.

For example, as shown in FIG. 13, the main processor assembly 4 is detachably connected to the bottom plate 23 through a hexagon head bolt 50. When the main processor assembly 4 needs to be removed, the main processor assembly 4 can be separated from the bottom plate 23 by rotating the hexagon head bolt 50.

In the embodiment, the main processor assembly 4 is detachably connected to the bottom plate 23, so that the main processor assembly 4 can be replaced and maintained simply and quickly, the maintainability and expandability of the server are effectively improved, and the maintenance cost is reduced. Meanwhile, it is also convenient to perform hardware upgrade according to actual requirements, so as to ensure that the server can continuously and stably operate and adapt to constantly changing application requirements.

In an exemplary embodiment, as shown in FIG. 1, the server further includes a pluggable optical module board 16 provided on the second side of the graphics processing card backplane 8 and connected to the graphics processing card backplane 8.

The pluggable optical module board may refer to a 100G optical port adapter board, and specifically may be a QSFP (Quad Small Form-factor Pluggable) board or a DSFP (Dual Small Form-factor Pluggable) board.

In the embodiment, by providing the pluggable optical module board, such as a 100G optical port adapter board (may be a QSFP or DSFP board), in the server, and arranging the pluggable optical module board on the second side of the graphics processing card backplane 8 and connecting the pluggable optical module board to the second side of the graphics processing card backplane 8, flexible configuration and expansion of a high-speed data transmission interface are achieved. Network bandwidth adjustment is facilitated according to actual requirements, a cabling process of network connection is simplified, maintainability and expandability of the server are improved, and it is ensured that the server can efficiently process a large-scale video transcoding task and provide a smooth online game experience.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. A server, comprising:
a housing provided with an accommodating cavity;
a main processor assembly accommodated in the accommodating cavity;
a graphics processing card assembly accommodated in the accommodating cavity;
a graphics processing card backplane accommodated in the accommodating cavity, wherein a gap is formed between the graphics processing card backplane and a bottom portion of the housing, a first side of the graphics processing card backplane is provided with a plurality of connecting interfaces, the graphics processing card assembly is connected to the plurality of connecting interfaces, a second side of the graphics processing card backplane is provided with a plurality of data transmission chips, and the plurality of data transmission chips are electrically connected to the plurality of connecting interfaces, respectively; and
a heat dissipation assembly provided adjacent to the graphics processing card assembly and in communication with external air, wherein the heat dissipation assembly is configured to dissipate heat from the graphics processing card assembly and the plurality of data transmission chips.

2. The server according to claim 1, further comprising a supporting member, wherein two ends of the supporting member are in contact with the second side of the graphics processing card backplane and the bottom portion of the housing, respectively, so as to form the gap between the graphics processing card backplane and the bottom portion of the housing.

3. The server according to claim 1, wherein the graphics processing card assembly comprises:
a limiting member provided with a plurality of limiting grooves; and
a plurality of graphics processing cards respectively accommodated in the plurality of limiting grooves and respectively electrically connected to the plurality of connecting interfaces.

4. The server according to claim 1, wherein the housing comprises an upper cover, a bottom plate, and two side plates, the two side plates are provided on two opposite sides of the bottom plate, respectively, the upper cover, the bottom plate, and the side plates cooperatively enclose the accommodating cavity, the housing further comprises two sliding rails symmetrically provided on the two side plates, and the graphics processing card assembly is slidably connected to the two side plates through the two sliding rails.

5. The server according to claim 4, wherein the housing further comprises a mounting structure fixedly connected to the bottom plate and the two side plates, and the mounting structure is detachably connected to the upper cover.

6. The server according to claim 5, wherein the heat dissipation assembly comprises a fan backplane and a plurality of heat dissipation fans connected to the fan backplane, the mounting structure comprises a plurality of fan limiting channels, and the plurality of heat dissipation fans are detachably mounted in plurality of fan limiting channels, respectively.

7. The server according to claim 4, further comprising a power supply assembly comprising a power supply backplane and a plurality of power supplies connected to the power supply backplane, wherein the mounting structure comprises a plurality of power supply limiting channels, and the plurality of power supplies are detachably mounted in the plurality of power supply limiting channels, respectively.

8. The server according to claim 4, further comprising a plurality of data transmission interfaces provided on an outer side wall of the side plate.

9. The server according to claim 4, wherein the main processor assembly is detachably connected to the bottom plate.

10. The server according to claim 1, further comprising a pluggable optical assembly board provided on the second side of the graphics processing card backplane and connected to the graphics processing card backplane.
